(19) United States
(12) Patent Application Publication
(10) Pub. No.: US 2026/0029276 A1
(43) Pub. Date: Jan. 29, 2026

(54) CALIBRATION OF AN OPTICAL SENSOR ARRANGEMENT

(71) Applicant: Inficon AG, Balzers (LI)

(72) Inventor: Stefan KAISER, Ruggell (LI)

(21) Appl. No.: 19/271,554

(22) Filed: Jul. 16, 2025

(30) Foreign Application Priority Data
Jul. 26, 2024 (CH) 000804/2024

(51) Int. Cl. G01J 3/02; G01J 3/28; H01J 37/32

(52) U.S. Cl. CPC G01J 3/0297; G01J 3/0291; G01J 3/28; G01J 2003/2879; H01J 37/32972; H01J 2237/24507

(57) ABSTRACT

Calibration device for calibrating the sensitivity of an optical sensor arrangement, wherein the calibration device comprises
a reflecting element with a reflecting region, said reflecting region comprising a multiplicity of reflecting faces varying in their orientation,
a light source able to provide light and arranged such that said divergent light from the light source is able to illuminate said reflecting region,
the optical sensor arrangement to be calibrated, wherein the optical sensor arrangement has an entrance opening for receiving incoming light and has at least a sensor for detecting light received through the entrance opening, and wherein said entrance opening is oriented towards said reflecting region, and
a light tight casing preventing light of origin outside the calibration device from entering said entrance opening. The invention is further directed to a method.

This application claims the benefit of priority to CH 000804/2024, filed 2024 Jul. 26, the contents of which are incorporated herein by reference in their entirely.

The invention addressed herein relates to a calibration device for calibrating the sensitivity of an optical sensor arrangement. Under further aspects, the invention relates to a method of calibrating an optical sensor arrangement.

When calibrating the sensitivity of an optical sensor arrangement, not only the actual sensitivity of a sensor element may play a role, but as well the whole arrangement of elements involved and in connection with this the possible light paths. As an illustrative example, the case of a remote plasma source (RPS) on a vacuum chamber is discussed in the following. The intensity of light emitted by the plasma, or may be even the spectral distribution of intensities, may be of interest. In order to characterize the state of an RPS on a vacuum chamber, typically the generated light is out-coupled at a viewport and guided to an optical spectrometer on the atmosphere (ATM) side and analyzed there in terms of light intensity as function of wavelength. Or a specific vacuum sensor, which combines a cold cathode pressure gauge and an internal spectrometer, is directly mounted on the vacuum chamber in order to catch the light into the internal optical spectrometer. The raw emission intensity measured can be used to monitor the actual RPS light quality and drift over time. If two or more RPS should be compared to each other, either the same device needs to be used for different chambers as reference “sensor” or as reference spectrometer. Alternatively, a reference RPS setup may be used to calibrate each sensor unit or each spectrometer unit. If there is no optical fiber used in the setup, this means that the OES sensor needs to be placed inside a vacuum chamber where a RPS is running, or that at least a surface of a sensor arrangement is exposed to the vacuum. This may lead to a pre-contamination of parts of the sensor arrangement. In addition, for with and without optical fibers related optical emission spectroscopy (OES) sensors, the usage of a RPS can have a high power consumption.

The object of the present invention is to provide an alternative apparatus or an alternative method, preferably reducing or avoiding the problems of the state of the art.

This object is achieved by a calibration device according to claim 1. It is a calibration device for calibrating the sensitivity of an optical sensor arrangement. The calibration device comprises
a reflecting element with a reflecting region, said reflecting region comprising a multiplicity of reflecting faces varying in their orientation,
a light source able to provide light and arranged such that said light from the light source is able to illuminate said reflecting region,
the optical sensor arrangement to be calibrated, wherein the optical sensor arrangement has an entrance opening for receiving incoming light and has at least a sensor for detecting light received through the entrance opening, and wherein said entrance opening is oriented towards said reflecting region, and
a light tight casing preventing light of origin outside the calibration device from entering said entrance opening. The reflecting faces may have surface normals varying over an angular range of at least 20°. This may be realized by a rough surface, wherein local surface normal deviate in their angle from an average surface geometry of the reflecting element, leading to a diffuse light reflection. As an alternative, an average surface geometry may have a variation of surface normals over a wide range, e.g. realized by a curved surface covering an angular range of 20° or more. Such an average curved surface may in addition have roughness as described before.

The light source may provide divergent light. The light source may be small compared to the reflecting region and the light may diverge strong enough to illuminate the reflecting region. Alternatively, the light source may have an extension large enough to illuminate the reflecting region. In this case, parallel light may be sent towards the reflecting region.

The light source may for example be a source of electromagnetic radiation covering essentially the visible part of the electromagnetic spectrum and optionally cover adjacent ultraviolet and infrared regions of the electromagnetic spectrum. As an example, the light source may emit in the wavelength range from 200 nm to 950 nm. The light source may be a broadband light source, it may emit monochromatic radiation or emit radiation in a set of a few narrow band regions. The light source may e.g. be realized by a light emitting diode.

This calibration device allows unit-to-unit calibration without the usage of an external RPS. Without RPS it is possible to simulate the light conditions as by having a RPS described by thousands of single point-like radiation sources distributed in space.

The optical sensor arrangement may e.g. be an optical spectrometer. More specifically, the optical spectrometer may be built into a cold-cathode vacuum gauge. In such an arrangement, the fact that the light source may be of the form of a cloud like distributed source and the fact that multiple different light paths are possible across the cold-cathode vacuum gauge part of the arrangement, the calibration device according to the invention leads by the use of simple means to a situation, which results in comparable calibration results, even if slight deviations in the geometry or orientation of the individual elements occur.

Embodiments of the device result from features of claims 2 to 4.

In one embodiment of the calibration device according to the invention, which may be combined with any of the embodiments still to be addressed unless in contradiction, said optical sensor arrangement comprises an optical spectrometer. The optical spectrometer may in particular comprise a photodiode array or an array of CCD CMOS sensors.

A calibration of an optical emission spectrometer may be performed with this type of calibration device.

In one embodiment of the calibration device according to the invention, which may be combined with any of the preaddressed embodiments and any of the embodiments still to be addressed unless in contradiction, said optical sensor arrangement further comprises a cold-cathode vacuum gauge, wherein elements of said cold-cathode vacuum gauge are arranged in a region between said entrance opening and said at least one sensor.

In the case of a spectrometer with an array of sensors, said elements of the cold-cathode vacuum gauge typically would be arranged in a region between the entrance opening and the spectrometer, i.e. the elements of the cold-cathode vacuum gauge are in a region between the entrance opening and all of the sensors of the array of sensors.

In one embodiment of the calibration device according to the invention, which may be combined with any of the preaddressed embodiments and any of the embodiments still to be addressed unless in contradiction, said reflecting element is a curved 90° elbow element having a reflecting inner surface, wherein said light source is positioned at a first end of said elbow element, wherein divergent light is directed towards a larger radius side of the inner surface, and wherein said entrance opening of said optical sensor arrangement is arranged on the second end of said elbow element.

The elbow element may be realized by a standard vacuum component. The elbow element has hollow interior, adapted to establish fluid connection between its first and second end. It may have vacuum flanges at the first and second end, for establishing vacuum tight connections to neighboring elements of a vacuum system.

The elbow element may have a hollow interior in form of a sector of a torus. Its cross section may have the same form and dimension from the first end to the second end. Alternatively, the cross section may vary, such as in the form of a horn.

Further in the scope of the invention lies the method according to claim 5. It is a method of calibrating an optical sensor arrangement, wherein the optical sensor arrangement has an entrance opening for receiving incoming light. The method comprising the steps:
providing a reflecting element with a reflecting region, said reflecting region comprising a multiplicity of reflecting faces varying in their orientation,
providing the optical sensor arrangement to be calibrated,
illuminating said reflecting region with light from a light source, let reflected light from the reflecting region enter through said entrance opening onto a sensor of the optical sensor arrangement,
measure a signal indicative for the light intensity of the light received at the sensor, and
compare said measured signal with previous reference measurements on a different optical sensor arrangement to calculate a calibration value.

The reflecting faces may vary in their orientation over an angular range of at least 20°.

The invention is further directed to a calibration method, wherein the calibration device according to any one of claims 1 to 4 is used.

The method may be further extended by steps after the calibration of the optical sensor is finished. The calibrated optical sensor arrangement may in a further step be mounted on a vacuum chamber at a position suitable for monitoring an optical emission of a plasma by means of the optical sensor arrangement.

The invention shall now be further exemplified with the help of figures. The figures show:

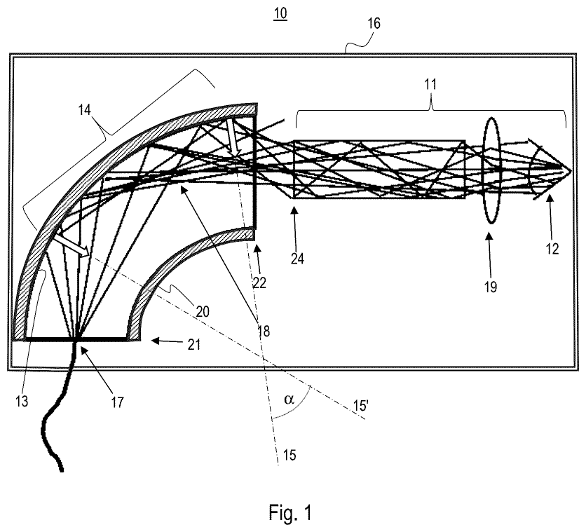

FIG. 1 a schematic, cross-sectional view of an embodiment of the calibration device;

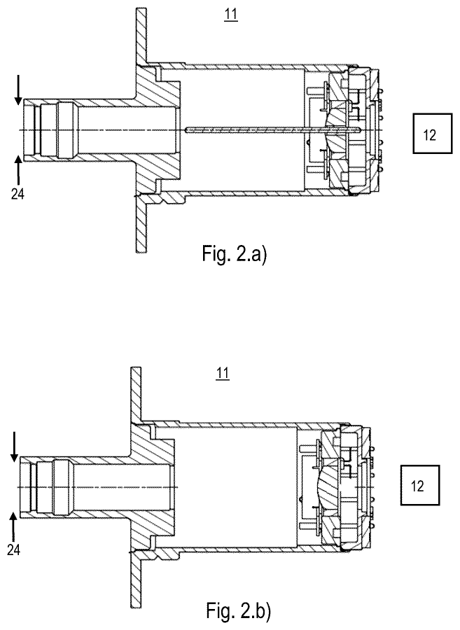

FIG. 2 shows in FIG. 2.a) and FIG. 2.b) two arrangements of elements of vacuum gauges to be calibrated;

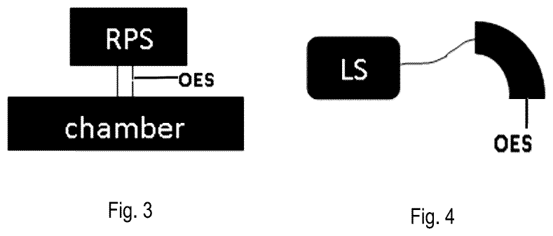

FIG. 3 shows schematically an arrangement of a optical emission spectroscopy (OES) device in relation to a vacuum chamber and a remote plasma source;

FIG. 4 shows schematically the calibration device in which the OES device may be calibrated.

FIG. 1 shows schematically and simplified, a calibration device 10 according to the invention.

Here, an external white light source 17 is guided into an optical fiber. The optical fiber is attached to a vacuum component that is “curved” by 90° (elbow). (here used a CF40-90° elbow). The divergent light is outcoupled out of the optical fiber and is shining into the elbow component, which here has the role of the reflecting element 13. As the light is divergent and the surface of the elbow is rough, the light is reflected at different locations with different incident angles. This leads to a highly un-collimated and spatially distributed light source on the other side of the elbow entering then finally the sensor, which may be an OES sensor, attached to the elbow.

The light shines on a reflecting area 14. Due to the curved form of the elbow, a multiplicity of reflecting surfaces of different orientations is present in the reflecting area. Two extreme cases of orientations are marked with hollow arrows pointing in direction of the orientations 15 and 15′. The angle between these extreme orientations is α, in this case larger than 30°. This angle may in the present case increased to up to 90° by illuminating a larger fraction of the elbow.

Here the light is coupled into to the sensor 12 by a lens 19.

Before the light arrives at the lens, it enters through an entrance opening 24 of the optical sensor arrangement and it may be reflected on various surfaces of the optical sensor arrangement 11.

FIG. 2.a) illustrates in an example the complex situation arising when elements of a cold-cathode vacuum gauge, here in the middle part of the figure, are combined with an optical sensor 12, which position is indicated symbolically and without showing details of the sensor, on the right side of the figure. The optical sensor in such a configuration may alternatively be used to analyze radiation emitted from a plasma generated around the central anode rode of the cold-cathode vacuum gauge and to analyze radiation originating from a remote plasma being located outside the present figure towards the left side. It is the latter use that profits from the calibration method according to the present invention. In this situation, light from the remote plasma enters trough the entrance opening 24. It may be reflected on several surfaces, before it exits through the lens, which in the case shown in FIG. 2.a) at the same time acts as a feedthrough for the central anode, and before it is finally detected in sensor 12. The cold-cathode vacuum gauge may comprise more elements not shown here in order not to overload the illustration. Such additional element may include an additional inner chamber and ferromagnetic elements arranged outside the housing shown here.

FIG. 2.b) shows a modified version of the optical sensor arrangement shown in FIG. 2.b), which makes use of similar element, but wherein the anode rod, which hinders radiation on its way from the entrance opening to the sensor 12, is removed.

FIG. 3 illustrates schematically a possible arrangement of a vacuum chamber (chamber), a remote plasma source (RPS), which is in fluid connection to the vacuum chamber, and a possible position of an optical emission spectrometer (OES), which may be used to monitor the state of the remote plasma source. The optical sensors of the OES may be calibrated by the method according to the present invention.

FIG. 4 illustrates schematically the arrangement that may be used to calibrate the OES, which is intended to be used in a configuration as shown in FIG. 3. In the embodiment shown here, a radiation from a light source (LS) is guided by an optical fiber to the first end of an elbow element, which is in this case realized by a curved, hollow vacuum component, providing a connection between a first and a second end oriented in 90° with respect to each other. The optical fiber guides light to the first end and illuminates the reflecting region in the interior of the elbow element, as is shown in more detail in FIG. 1. The optical sensor arrangement to be calibrated, in this case the OES, is positioned at the second end of the elbow element. The inventor has realized that an arrangement as illustrated in FIG. 4 is surprisingly able to represent essential features of the different arrangement shown in FIG. 3 at least with respect to its impact on the calibration of the optical sensor.

### LIST OF REFERENCE SIGNS

10 calibration device
11 optical sensor arrangement
12 sensor
13 reflecting element
14 reflection region
15, 15′ angular orientation
16 light tight casing
17 light source
18 light paths
19 lens
20 elbow element
21 first end of elbow element
22 second end of elbow element
23 elements of cold-cathode vacuum gauge
24 entrance opening
α angular range
RPS remote plasma source
LS light source
OES optical emission spectroscope

1. Calibration device (10) for calibrating the sensitivity of an optical sensor arrangement (11), wherein the calibration device comprises
a reflecting element (13) with a reflecting region (14), said reflecting region comprising a multiplicity of reflecting faces varying in their angular orientation (15, 15′),
a light source (17) able to provide light and arranged such that said divergent light from the light source is able to illuminate said reflecting region (14),
the optical sensor arrangement (11) to be calibrated, wherein the optical sensor arrangement has an entrance opening (24) for receiving incoming light and has at least a sensor (12) for detecting light received through the entrance opening, and wherein said entrance opening is oriented towards said reflecting region, and
a light tight casing (16) preventing light of origin outside the calibration device from entering said entrance opening.

2. Calibration device according to claim 1, wherein said optical sensor arrangement comprises an optical spectrometer, in particular comprising a photodiode array or an array of CCD CMOS sensor.

3. Calibration device according to claim 1, wherein said optical sensor arrangement further comprises a cold-cathode vacuum gauge, wherein elements of said cold-cathode vacuum gauge are arranged in a region between said entrance opening and said at least one sensor.

4. Calibration device according to claim 1, wherein said reflecting element is a curved 90° elbow element having a reflecting inner surface, wherein said light source is positioned at a first end (21) of said elbow element, wherein divergent light is directed towards a larger radius side of the inner surface, and wherein said entrance opening of said optical sensor arrangement is arranged on a second end (22) of said elbow element.

5. Method of calibrating an optical sensor arrangement, wherein the optical sensor arrangement has an entrance opening for receiving incoming light, the method comprising the steps:
providing a reflecting element with a reflecting region, said reflecting region comprising a multiplicity of reflecting faces varying in their orientation,
providing the optical sensor arrangement to be calibrated,
illuminating said reflecting region with light from a light source, let reflected light from the reflecting region enter through said entrance opening onto a sensor of the optical sensor arrangement,
measure a signal indicative for the light intensity of the light received at the sensor, and
compare said measured signal with previous reference measurements on a different optical sensor arrangement to calculate a calibration value.

6. Method according to claim 5, wherein a calibration device (10) is used, the calibration device (10) comprising:
a reflecting element (13) with a reflecting region (14), said reflecting region comprising a multiplicity of reflecting faces varying in their angular orientation (15, 15′),
a light source (17) able to provide light and arranged such that said divergent light from the light source is able to illuminate said reflecting region (14),
the optical sensor arrangement (11) to be calibrated, wherein the optical sensor arrangement has an entrance opening (24) for receiving incoming light and has at least a sensor (12) for detecting light received through the entrance opening, and wherein said entrance opening is oriented towards said reflecting region, and
a light tight casing (16) preventing light of origin outside the calibration device from entering said entrance opening.

7. Method according to claim 5, wherein the calibrated optical sensor arrangement in a further step is mounted on a vacuum chamber at a position suitable for monitoring an optical emission of a plasma by means of the optical sensor arrangement.
